(19) United States
(12) Patent Application Publication
(10) Pub. No.: US 2007/0081880 A1
(43) Pub. Date: Apr. 12, 2007

(54) Wafer-handling method, system, and apparatus

(76) Inventors: Benjamin B. Riordon, Newburyport, MA (US); Lawrence M. Ficarra, Billerica, MA (US); James Buonodono, Amesbury, MA (US)

Correspondence Address: VARIAN SEMICONDUCTOR EQUIPMENT ASSC., INC., 35 DORY RD., GLOUCESTER, MA, 01930-2297, US

(21) Appl. No.: 11/238,777

(22) Filed: Sep. 29, 2005

(51) Int. Cl. H01L 21/677

(52) U.S. Cl. 414/217

(57) ABSTRACT

The invention provides a wafer-handling method, system, and apparatus. In one embodiment, the invention provides a wafer-handling apparatus comprising: a clamping surface for securing a wafer; and a load lock sealing surface for forming an airtight seal with a load lock wall.

### BACKGROUND OF-THE INVENTION

1. Technical Field

The invention relates generally to ion implantation, and more particularly, to a method, system, and apparatus for wafer handling associated with ion implantation.

2. Background Art

In a single-wafer, serial-processing ion implanter, a wafer is transferred in a vacuum chamber from a load lock to a process station and back. This process requires multiple transfers of the wafer from one wafer-handling device to another, each transfer increasing the risk of wafer breakage, backside particle generation, and wafer misplacement and/or misorientation. In addition, multiple transfers increases both the complexity of the ion implantation and the time necessary to complete the process.

For example, FIG. 1 shows a diagram of a typical known method 1 for transferring a wafer during ion implantation. First, at step S1, a wafer is removed from a wafer pod 10. Typically, this is accomplished using an atmospheric wafer-handling robot 20 having an end effector. Next, at step S2, atmospheric robot 20 places the wafer into an open load lock 30, which is then sealed and its atmosphere evacuated. Once evacuated, load lock 30 is opened to a vacuum chamber (not shown). At step S3, a vacuum robot 40 having an end effector removes the wafer from load lock 30 and, at step S4, places the wafer on a wafer aligner 50. Wafer aligner 50 rotates the wafer through an edge sensor (not shown), which detects the wafer's orientation and position and aligns it for implantation. At step S5, vacuum robot 60 (which may be the same vacuum robot as vacuum robot 40 or a different vacuum robot) removes the aligned wafer from wafer aligner 50 and, at step S6, places the wafer in a process station 70, where ion implantation takes place. Following implantation, at step S7, vacuum robot 60 removes the wafer from process station 70 and, at step S8, returns the wafer back to load lock 30. Load lock 30 is closed and vented, returning it to atmospheric pressure. Finally, at steps S9 and S10, respectively, atmospheric robot 20 retrieves the wafer from load lock 30 and returns it to wafer pod 10.

As can be seen from FIG. 1, known methods of wafer transfer include numerous wafer-handling devices and repeated transfers of the wafer between these devices. Each transfer increases the risk that the wafer will be damaged, become misaligned, and/or suffer backside particle generation. In addition, each transfer adds time to the overall ion implantation process, reducing its efficiency and cost-effectiveness.

To this extent, a need exists for a method, system, and apparatus for simplifying wafer-handling processes associated with ion implantation. In particular, it would be advantageous to simplify wafer-handling in portions of the ion implantation process occuring with a vacuum (i.e., at subatmospheric pressure), where space is generally limited and it is preferable to utilize a minimum number of wafer-handling devices.

### SUMMARY OF THE INVENTION

The invention provides a wafer-handling method, system, and apparatus. In one embodiment, the wafer-handling apparatus includes a load lock sealing surface for forming an airtight seal with a load lock wall.

A first aspect of the invention provides a wafer-handling apparatus comprising: a clamping surface for securing a wafer; and a load lock sealing surface for forming an airtight seal with a load lock wall.

A second aspect of the invention provides a method of transferring a wafer between chambers, the method comprising the steps of: sealing a clamp mechanism to a surface of a load lock wall; and transferring the wafer from a first chamber to a second chamber.

A third aspect of the invention provides an ion implantation wafer-handling system comprising: means for sealing a clamp mechanism to a surface of a load lock wall; and means for transferring the wafer from a first chamber to a second chamber.

A fourth aspect of the invention provides a wafer-handling apparatus comprising: an electrostatic clamping surface including a plastic material.

A fifth aspect of the invention provides a load lock chamber having: a first port; a sealing member for sealing the first port; and a second port adapted to form a seal with a wafer-handling apparatus.

The illustrative aspects of the present invention are designed to solve the problems herein described and other problems not discussed, which are discoverable by a skilled artisan.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a flow diagram of a prior art wafer-handling method.

FIG. 2 shows a perspective view of a wafer-handling apparatus according to one embodiment of the invention.

FIGS. 3A-B show perspective views of illustrative alternative embodiments of a clamp mechanism according to the invention.

FIGS. 4A-B show exploded side views of illustrative alternative embodiments of a clamp mechanism according to the invention.

FIG. 5A shows a pair of wafer-handling apparatuses in conjunction with a load lock and an ion implantation process chamber according to one embodiment of the invention.

FIG. 5B shows a side view of a clamp mechanism forming a seal with a load lock wall according to one embodiment of the invention.

FIG. 6 shows a schematic diagram of a coordinated wafer-handling method including two wafer-handling apparatuses.

FIG. 7 shows a flow diagram of a wafer-handling method according to one embodiment of the invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION OF THE INVENTION

As indicated above, the invention provides a wafer-handling method, system, and apparatus.

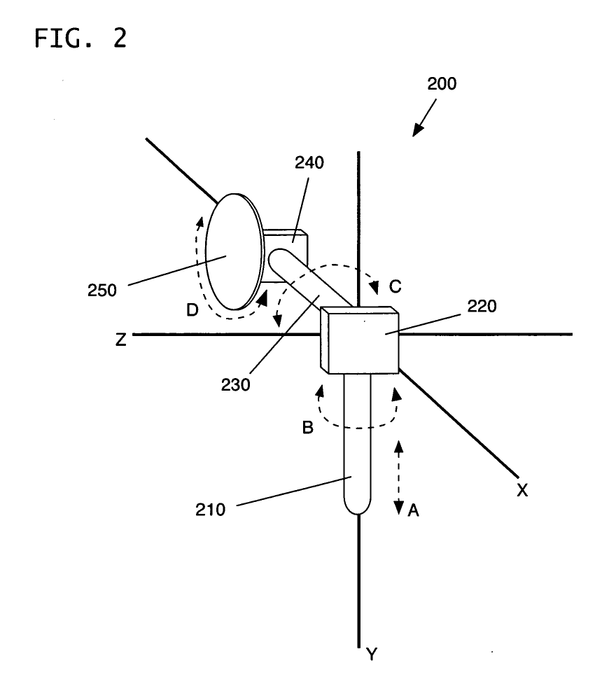

Turning to the drawings, FIG. 2 shows an illustrative embodiment of a wafer-handling apparatus 200 of the invention. Appratus 200 comprises a Y-axis shaft 210, and an X-axis shaft 230, a plurality of rotation devices 220, 240, and a clamp mechanism 250 for holding a wafer. Each of Y-axis shaft 210 and X-axis shaft 230 is rotatable about its respective axis (i.e., Y-axis shaft 210 is rotatable about the Y-axis along path B and X-axis shaft 230 is rotatable about the X-axis along path C). In addition, clamp mechanism 250 is rotatable about the Z-axis along path D.

Each of the above rotations is accomplished by a rotation device 220, 240. Rotation device 220, 240 may be any known or later-developed device capable of rotating a shaft 210, 230 or clamp mechanism 250 about an axis, e.g., a motor. Each rotation device 220, 240 may rotate a single shaft 210, 230 or clamp mechanism 250, a pair of shafts 210, 230, or a shaft 230 and a clamp mechanism 250. For example, rotation device 220 may be adapted to rotate X-axis shaft 230 about the X-axis only or may be adapted to also rotate Y-axis shaft 210 about the Y-axis. Similarly, rotation device 240 may be adapted to rotate clamp mechanism 250 about the Z-axis only or may be adapted to also rotate X-axis shaft 230 about the X-axis.

It should be recognized that it is not necessary that either shaft 210, 230 actually rotate about its corresponding axis. For example, rather than Y-axis shaft 210 itself rotating about the Y-axis, it is within the scope of the present invention that the components of apparatus 200 connected to Y-axis shaft 210 (i.e. rotating device 220, X-axis shaft 230, rotating device 240, and clamp mechanism 250) rotate about the Y-axis. With respect to the ion implantation process, either rotation method is acceptable.

As shown in FIG. 2, Y-axis shaft 210 is also movable along path A, i.e., along a length of the Y-axis. Such movement adds an additional degree of freedom to apparatus 200, permitting movement of a wafer attached to clamp mechanism 250 in and out of an ion beam. In addition, as will be described in greater detail below, in a preferred embodiment, the movement of apparatus 200 along path A permits clamp mechanism 250 to form a seal with a load lock (not shown).

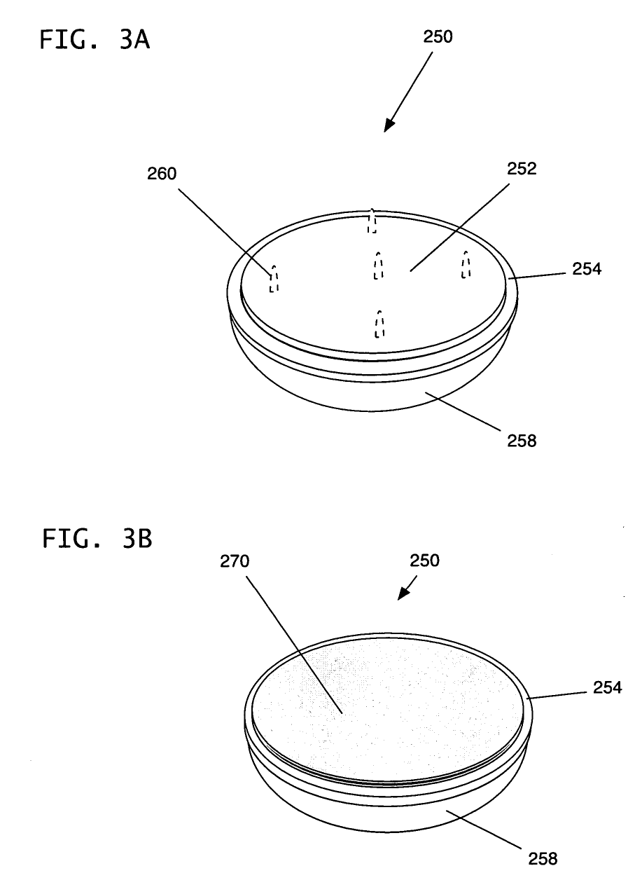

Referring now to FIGS. 3A-B, detailed views of two embodiments of clamp mechanism 250 are shown. Clamp mechanism 250 comprises a clamping surface 252, a load lock sealing surface 254, and a base portion 258. As shown, load lock sealing surface 254 comprises a planar surface having an annular shape and is located along a circumference of clamping surface 252. Load lock sealing surface 254 may, of course, be of other shapes, including, for example, square, rectangular, and ovoid. Load lock sealing surface 254 is adapted to form an airtight seal against a wall of a load lock (not shown), such that the load lock may be evacuated.

In FIG. 3A, a plurality of retractable lift pins 260 are shown. Lift pins 260 extend upward from and retract to a position below or flush with clamping surface 252, thereby raising and lowering a wafer relative to clamping surface 252. This arrangement permits a wafer to be released from clamping surface 252 by raising lift pins 260 and lowered onto clamping surface 252 by retracting lift pins 260.

Still referring to FIG. 3A, clamping surface 252 and load lock sealing surface 254 are depicted as parallel planar surfaces, with clamping surface 252 residing “proud” of load lock sealing surface 254. In an alternative embodiment, clamping surface 252 and load lock sealing surface 254 are coplanar.

Clamping surface 252 provides a surface to which a wafer (not shown) may be secured. Preferably, clamping mechanism 250 is an electrostatic clamp and a wafer is secured to clamping surface 252 by electrostatic force. Any known or later-developed method for imparting an electrostatic force to clamping surface 252 may be employed. For example, clamping surface 252 may comprise a monopole electrostatic chuck, a bipolar electrostatic chuck, a tri-polar electrostatic chuck, a multi-pole electrostatic chuck, or an anodized aluminum electrostatic chuck. In one embodiment, clamping surface 252 includes a ceramic. In an alternative embodiment, described in greater detail below, clamping surface 252, an insulator layer (not shown), and/or base portion 258, include a plastic material having a dielectric constant similar to that of a ceramic.

Referring now to FIG. 3B, a wafer 270 is shown electrostatically clamped to clamping surface 252. In this case, clamping surface 252 and load lock sealing surface 254 are coplanar. As such, wafer 270 resides above load lock sealing surface 254 to a height equal to a thickness of wafer 270. Preferably, a diameter of wafer 270 is greater than a diameter of clamping surface 252, such that a wafer clearance is formed by a portion of wafer 270 beyond an inner circumference of load lock sealing surface 254. Such an arrangement prevents an ion beam from striking clamping surface 252, should wafer 270 be misaligned. The lower limit of the wafer clearance range is dictated by the amount of placement error by the atmospheric robot to be compensated for. The upper limit of the wafer clearance range is limited only by the size of the wafer-handling system, provided it does not interfere with the functioning of load lock sealing surface 254. Typically, the wafer clearance is between about 0.005″ and about 3.0″.

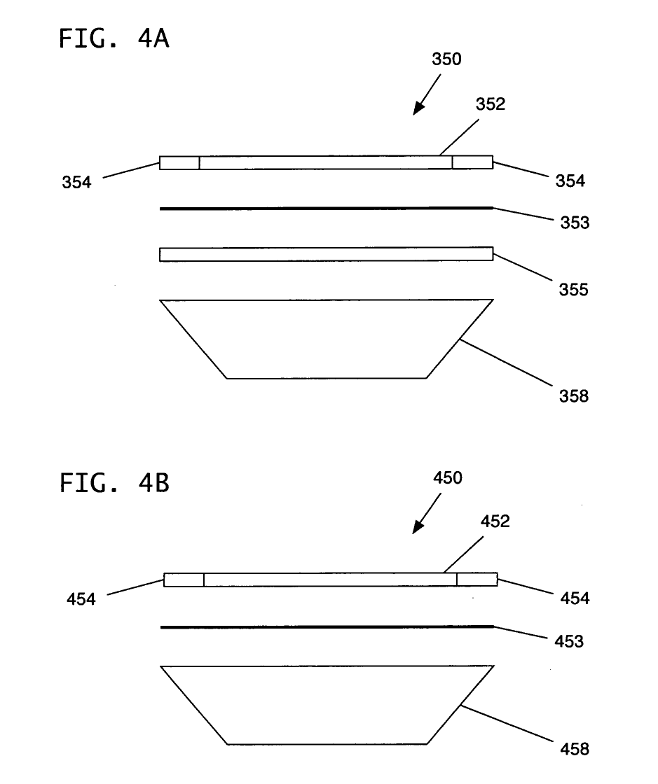

Referring now to FIGS. 4A-B, two exploded side views of alternative embodiments of clamp mechanism 350, 450 are shown. In FIG. 4A, electrodes 353 reside between a layer comprising clamping surface 352 and load lock sealing surface 354 and an insulator layer 355. As depicted, clamping surface 352 and load lock sealing surface 354 are coplanar. Electrodes 353 may impart an alternating or direct current to clamping surface 352, permitting electrostatic clamping of a wafer (not shown) to clamping surface 352. In known clamp mechanisms, both clamping surface 352 and insulator layer 355 are generally a ceramic; typically alumina. However, as depicted in FIG. 4A, the ceramic of one or both of clamping surface 352 and insulator layer 355 has been replaced by a plastic material having electrical characteristics similar to that of a ceramic. In particular, the plastic has a dielectric constant similar to that of a ceramic, which enables the plastic of clamping surface 352 to impart an electrostatic force sufficient to secure a wafer to clamp mechanism 350. Preferably, the plastic has a dielectric constant between about 8.0 and about 9.5. In a particularly preferred embodiment, the plastic is polyvinylidene fluoride (PVDF), such as KYNAR® 460, having a dielectric constant of approximately 9.0, available from Westlake® Plastics Company.

Base member 358, residing directly adjacent insulator layer 355, is typically composed of aluminum. As such, base member 358 may act as a heat sink, dispersing heat caused by the electrostatic clamping force away from the wafer (not shown). In an alternative embodiment of the invention, base member 358 may similarly include a plastic material. The plastic material may be the same as or different than the plastic material of clamping surface 352 or insulator layer 355.

Referring to FIG. 4B, an alternative embodiment of clamp mechanism 450 is shown, wherein both clamping surface 452 and base portion 458 include a plastic material, as described above. Accordingly, insulator layer 355 (FIG. 4A) may be omitted, as base portion 458 may serve the function of insulator layer 355 (FIG. 4A) in generating an electrostatic clamping force. Therefore, electrodes 453 are positioned between clamping surface 452 and base portion 458.

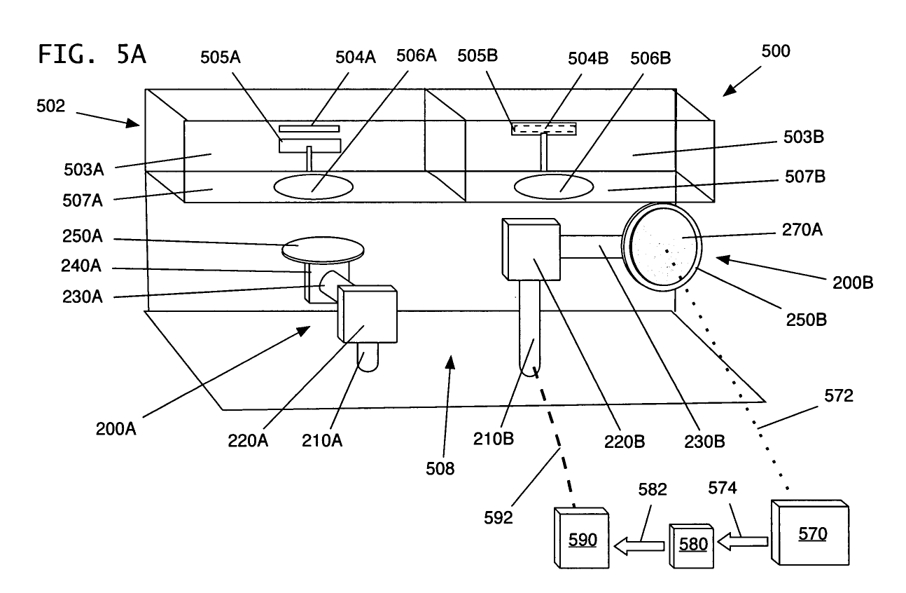

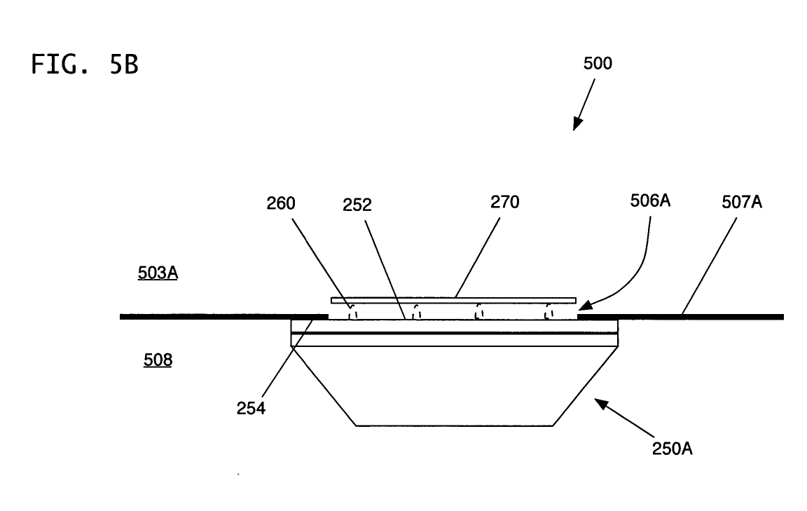

Referring now to FIG. 5A, a diagram of an ion implantation wafer-handling system 500 is shown comprising a pair of wafer-handling apparatuses 200A, 200B, a load lock 502, and a process chamber 508. Load lock 502 includes a pair of load lock chambers 503A, 503B, each of which includes a pair of ports (i.e., holes in wall 504) 504A, 504B, 506A, 506B. A first port 504A, 504B, generally a slot valve, allows passage of wafers into load lock chamber 503A, 503B using an atmospheric robot. First port 504A, 504B includes a port sealing member 505A, 503B for forming an airtight seal between load lock chamber 503A, 503B and an atmosphere outside load lock 502, enabling the formation of a vacuum (i.e., subatmospheric) pressure within load lock chamber 503A, 503B. As shown, port 504A is “open,” i.e., port sealing member 505A does not cover port 504A, while port 504B is “closed,” i.e., port sealing member 505B covers port 504B.

A second port, 506A, 506B allows transfer of a wafer from load lock chamber 503A, 503B to a wafer-handling apparatus 200A, 200B inside process chamber 508. As described above with respect to FIGS. 3A-B, a clamp mechanism 250A, 250B of each apparatus 200A, 200B includes a load lock sealing surface 254 (FIGS. 3A-B) adapted to form an airtight seal with a wall 507A, 507B of load lock 502 adjacent ports 506A, 506B. As such, second port 503A, 503B does not require a port sealing member, as does first port 504A, 504B. As also described above, load lock chamber 503A, 503B may be at atmospheric pressure or vacuum (i.e., subatmospheric) pressure while process chamber 508 is preferably maintained at a vacuum (subatmospheric) pressure.

As described above with respect to FIG. 2, each wafer-handling apparatus 200A, 200B includes a Y-axis shaft 210A, 210B, an X-axis shaft 230A, 230B, a clamp mechanism 250A, 250B, and rotation devices 220A, 220B, 240A (an additional rotation device is hidden behind clamp mechanism 250B).

Referring now to FIG. 5B, a side view of a clamp mechanism 250A is shown wherein load lock sealing surface 254 forms an airtight seal with a portion of wall 507A adjacent second port 506A. As shown, wafer 270 resides adjacent lift pins 260, which are raised from clamping surface 252. Thus, wafer 270 resides within load lock chamber 503A while clamp mechanism 250A resides within process chamber 508.

Returning to FIG. 5A, once load lock chamber 503A is evacuated, load lock sealing surface 254 is unseated from wall 504. Apparatus 200A may then be lowered along and rotated about Y-axis shaft 210A to a pre-implantation position. Apparatus 200A may further be rotated about X-axis shaft to reach the pre-implantation position. Once in the pre-implantation position, an imaging system (e.g., a digital imaging system) 570 scans 572 a surface of wafer 270A. Data is then transmitted 574 from imaging system 570 to a determinator 580, which determines a proper orientation of wafer 270A for ion implantation using known algorithms. Data from determinator 580 is then transmitted 582 to a wafer orienter 590, which transmits 592 orientation data to apparatus 200B. As described above with respect to FIG. 2, apparatus 200A may maneuver about the X- and Z-axes and about and along the Y-axis to position wafer 270A in the orientation determined by determinator 580.

Following ion implantation, apparatus 200A returns to a position such that clamp mechanism 250A is beneath second port 506A and load lock sealing surface 254 (FIGS. 3A-B) forms an airtight seal against wall 507A, as in FIG. 5B. Load lock chamber 503A is then vented and lift pins 260 (FIG. 3A), if employed, may simultaneously be raised to lift wafer 270A. Port sealing member 505A unseals first port 504A and an atmospheric robot (not shown) may then remove wafer 270A from load lock chamber 503A.

As depicted in FIG. 5A, wafer-handling system 500 includes a pair of wafer-handling apparatuses 200A, 200B. It should be noted, however, that a wafer-handling system according to the invention may also include one wafer-handling apparatus or more than two wafer-handling apparatuses. In any system 500 having more than one wafer-handling apparatus, the speed and efficiency of the ion implantation process can be improved by coordinating the operations of each apparatus.

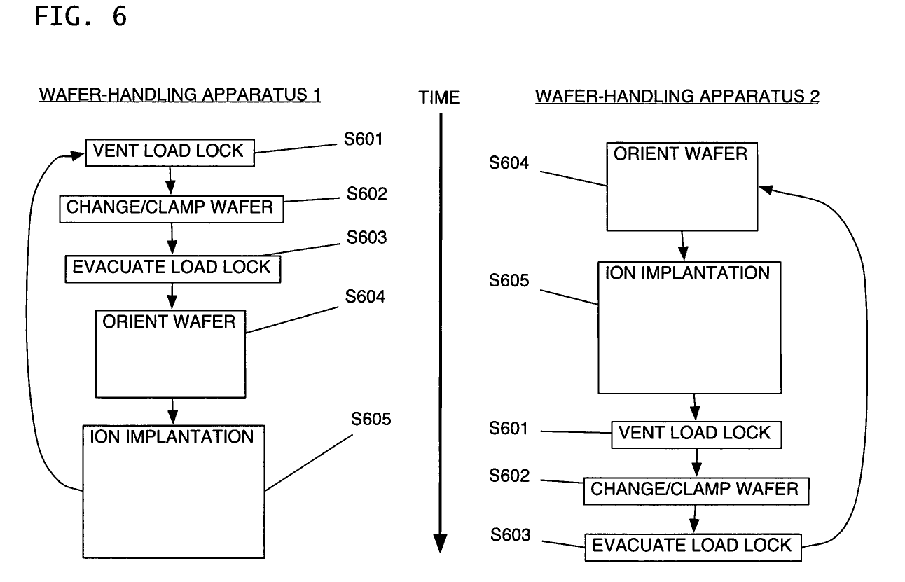

For example, referring now to FIG. 6, the coordinated processes of two wafer-handling apparatuses is shown. As depicted, each apparatus performs five process steps: venting the load lock at step S601, clamping a wafer at step S602 (if other than the first wafer processed, step S602 includes changing the processed wafer for an unprocessed wafer), evacuating the load lock at step S603, orienting the wafer at step S604, and performing an ion implantation at step S605. Each apparatus then repeats each of the five process steps. However, the steps performed by each apparatus are staggered such that the same process steps are not simultaneously performed by each apparatus. This is particularly important during the wafer orientation and ion implantation steps, which may utilize devices common to both apparatuses (e.g., a digital imaging system, an ion beam source, etc.).

In addition, the movements of each apparatus may be coordinated to avoid collision and improve efficiency. For example, one apparatus may utilize a pre-implantation position above the ion beam while another apparatus utilizes a pre-implantation position below the ion beam. Proper coordination of apparatus movements may, in some instances, even permit some overlap in process steps. For example, using a single ion beam, one apparatus may be completing the ion implantation step (S605 in FIG. 6) as another apparatus is beginning the ion implantation step.

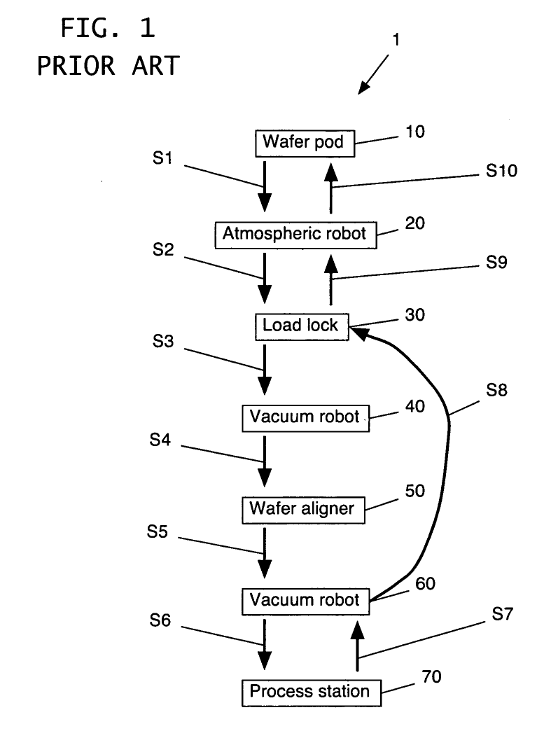

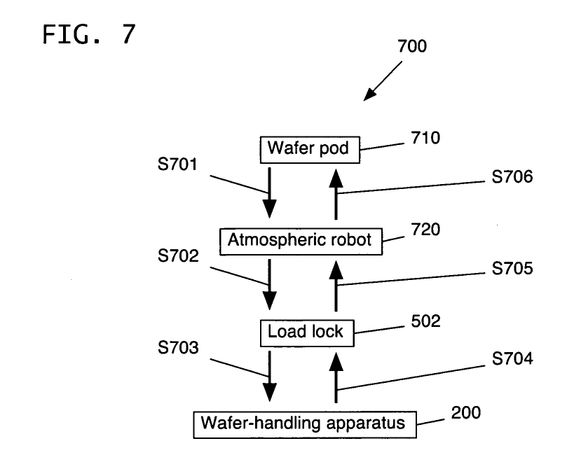

Referring now to FIG. 7, an illustrative wafer-handling method 700 is shown. The first two steps of method 700 (i.e., steps S701 and S702) are substantially the same as those described above with respect to FIG. 1. That is, at step S701, an atmospheric robot 720 removes a wafer from a wafer pod 710 and, at step S702, places the wafer within a load lock 502 (FIG. 5A). However, as described above with respect to FIGS. 2, 3A-B, 5, and 6, unlike known methods (such as that of FIG. 1), the transfer of the wafer from load lock 502 to wafer-handling apparatus 200 (FIG. 2) includes the formation of an airtight seal between load lock sealing surface 254 (FIGS. 3A-B) and a wall (e.g., 507A of FIG. 5A) of load lock 502. In addition, following the transfer of the wafer to wafer-handling apparatus 200, all subsequent steps in the ion implantation process (e.g., wafer alignment and ion implantation) may be performed with the wafer secured to wafer-handling apparatus 200. That is, it is possible to perform an ion implantation of a wafer with no wafer transfers inside process chamber 508 (FIGS. 5A-B). Once ion implantation is complete, wafer-handling apparatus 200 returns the wafer to load lock 502 at step S704. Again, step S704 includes the formation of an airtight seal between load lock sealing surface 254 (FIGS. 3A-B) and a wall (e.g., 507A of FIGS. 5A-B) of load lock 502. Once load lock 502 is vented, atmospheric robot 720 removes the wafer at step S705 and returns the wafer to wafer pod 710 at step S706.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A wafer-handling apparatus comprising:
a clamping surface for securing a wafer; and
a load lock sealing surface for forming an airtight seal with a load lock wall.

2. The wafer-handling apparatus of claim 1, wherein the clamping surface and the load lock sealing surface are coplanar.

3. The wafer-handling apparatus of claim 1, wherein the clamping surface includes a plastic and is adapted to secure the wafer using an electrostatic force.

4. The wafer-handling apparatus of claim 3, wherein the plastic has a dielectric constant between about 8.0 and about 9.5.

5. The wafer-handling apparatus of claim 4, wherein the plastic includes polyvinylidene fluoride (PVDF).

6. The wafer-handling apparatus of claim 3, further comprising a base portion including at least one of: aluminum and a plastic.

7. The wafer-handling apparatus of claim 6, wherein the base portion includes a plastic having a dielectric constant between about 8.0 and about 9.5.

8. The wafer-handling apparatus of claim 7, wherein the plastic includes polyvinylidene fluoride (PVDF).

9. The wafer-handling apparatus of claim 3, wherein the clamping surface is adapted to be powered by one of: alternating current and direct current.

10. The wafer-handling apparatus of claim 1, further comprising at least one retractable lift pin for raising and lowering the wafer.

11. A method of transferring a wafer between chambers, the method comprising the steps of:
sealing a clamp mechanism to a surface of a load lock wall; and
transferring the wafer from a first chamber to a second chamber.

12. The method of claim 11, wherein the first chamber is a load lock chamber and the second chamber is a process chamber.

13. The method of claim 11, wherein the clamp mechanism includes a load lock sealing surface and a clamping surface.

14. The method of claim 13, wherein the load lock sealing surface and the clamping surface are coplanar.

15. The method of claim 13, further comprising the step of securing the wafer to the clamping surface via an electrostatic force.

16. The method of claim 13, wherein the clamping surface is adapted to be powered by one of: alternating current and direct current.

17. The method of claim 16, wherein the clamping surface includes a plastic.

18. The method of claim 17, wherein the plastic has a dielectric constant between about 8.0 and about 9.5.

19. The method of claim 18, wherein the plastic includes polyvinylidene fluoride (PVDF).

20. The method of claim 17, wherein the clamp mechanism further comprises a base portion including at least one of: aluminum and a plastic.

21. The method of claim 20, wherein the base portion includes a plastic having a dielectric constant between about 8.0 and about 9.5.

22. The method of claim 21, wherein the plastic includes polyvinylidene fluoride (PVDF).

23. An ion implantation wafer-handling system comprising:
means for sealing a clamp mechanism to a surface of a load lock wall; and
means for transferring the wafer from a first chamber to a second chamber.

24. The system of claim 23, wherein the clamp mechanism includes:
a clamping surface for securing the wafer; and
a load lock sealing surface for forming an airtight seal with a load lock wall.

25. The system of claim 24, wherein the clamping surface and the load lock sealing surface are coplanar.

26. The system of claim 24, wherein the clamping surface includes a plastic and is adapted to secure the wafer using an electrostatic force.

27. The system of claim 26, wherein the plastic has a dielectric constant between about 8.0 and about 9.5.

28. The system of claim 27, wherein the plastic includes polyvinylidene fluoride (PVDF).

29. The system of claim 23, further comprising:
means for determining an orientation of the wafer for ion implantation; and
means for orienting the wafer for ion implantation.

30. The system of claim 29, wherein the means for determining includes an imaging device.

31. A wafer-handling apparatus comprising:
an electrostatic clamping surface including a plastic material.

32. The wafer-handling apparatus of claim 31, wherein the plastic has a dielectric constant between about 8.0 and about 9.5.

33. The wafer-handling apparatus of claim 32, wherein the plastic includes polyvinylidene fluoride (PVDF).

34. A load lock chamber having:
a first port;
a sealing member for sealing the first port; and
a second port adapted to form a seal with a wafer-handling apparatus.

35. The load lock chamber of claim 34, wherein the first port is a slot valve.

36. The load lock chamber of claim 34, wherein the second port opens to a process chamber.
